(19) United States
(12) Patent Application Publication
(10) Pub. No.: US 2007/0145376 A1
(43) Pub. Date: Jun. 28, 2007

(54) Gallium Nitride Crystal Substrate, Semiconductor Device, Method of Manufacturing Semiconductor Device, and Method of Identifying Gallium Nitride Crystal Substrate

(75) Inventors: Manabu Okui, Itami-shi (JP); Ken-ichiro Miyatake, Osaka-shi (JP); Hideaki Nakahata, Itami-shi (JP); Shinsuke Fujiwara, Itami-shi (JP); Seiji Nakahata, Itami-shi (JP)

Correspondence Address: JUDGE & MURAKAMI IP ASSOCIATES, DOJIMIA BUILDING, 7TH FLOOR, 6-8 NISHITEMMA 2-CHOME, KITA-KU, OSAKA-SHI, 530-0047, JP

(73) Assignee: SUMITOMO ELECTRIC INDUSTRIES, LTD., Osaka-shi (JP)

(21) Appl. No.: 11/616,016

(22) Filed: Dec. 26, 2006

(30) Foreign Application Priority Data
Dec. 26, 2005 (JP) JP-2005-372547

(51) Int. Cl. H01L 29/15

(52) U.S. Cl. 257/76

(57) ABSTRACT

Affords GaN crystal substrates that can reduce the occurring of cracks and fractures in the GaN crystal substrates when the semiconductor devices are manufactured, semiconductor devices including them, methods of manufacturing the semiconductor devices, and methods of identifying the GaN crystal substrates. A gallium nitride crystal substrate has a surface area of 10 cm² or more. The difference between the maximum and the minimum of Raman shifts corresponding to the E_{2H} phonon mode in a region except for a region from the outer periphery in the surface of the gallium nitride crystal substrate to a line 5 mm radially inward from the outer periphery of the surface is 0.5 cm⁻¹ or less. And also affords semiconductor devices including them, methods of manufacturing the semiconductor devices, and methods of identifying the GaN crystal substrates.

### BACKGROUND OF THE INVENTION

1. Technical Field

The present invention relates to gallium nitride (GaN) crystal substrates, semiconductor devices, methods of manufacturing the semiconductor devices, and methods of identifying the GaN crystal.

2. Description of the Related Art

GaN crystal substrates, among nitride semiconductor crystal substrates, have received attention as substrates for semiconductor devices such as light-emitting devices and electron devices. At present, the generally employed way of manufacturing GaN crystal substrates is a method in which GaN crystal is vapor-deposited onto a sapphire substrate by hydride vapor phase epitaxy (HVPE) or a similar technique.

Also, semiconductor devices employing GaN crystal substrates are manufactured by vapor-depositing one or more nitride semiconductor crystal layers onto a GaN crystal substrate by metalorganic chemical vapor deposition (MOCVD) or a similar technique, then forming electrodes onto the devices, and finally dicing them into chips.

To reduce costs in manufacturing semiconductor devices, it is advantageous to vapor-deposit nitride semiconductor crystal layers onto GaN crystal substrates having surfaces as large as possible, so that as many semiconductor devices as possible can be obtained from a single GaN crystal substrate.

However, the larger the surface of the GaN crystal substrate is to be, the greater becomes the likelihood that cracks or fractures occur in the GaN crystal substrates when semiconductor devices are manufactured on them. The occurrence of cracks or fractures in the GaN crystal substrates during device manufacture leads to a high frequency of defective products, and to GaN crystal substrate fragments scattering onto the semiconductor device manufacturing equipment, inhibiting continuous production, which not only is prohibitive of reducing device manufacturing costs, but also presents the possibility that the device characteristics will be compromised. A need has therefore been felt to develop GaN crystal substrates that make it possible to reduce the incidence of cracking and fracturing when semiconductor devices are fabricated on the substrates.

### BRIEF SUMMARY OF THE INVENTION

It is an object of the present invention to make available GaN crystal substrates that can reduce the incidence of cracking and fracturing in the substrates during semiconductor device manufacture, and to make available semiconductor devices incorporating the GaN crystal substrates, methods of manufacturing the semiconductor devices, and methods of identifying the GaN crystal substrates.

One aspect of the present invention is a GaN crystal substrate having a front side whose surface area is 10 cm² or more, and therein is GaN crystal substrate in which, within a region of the front side of the substrate excepting the margin to 5 mm inward from the peripheral edge, the difference between the maximum and minimum Raman shifts corresponding to the E_{2H} phonon mode is 0.5 cm⁻¹ or less.

Another aspect of the present invention is a GaN crystal substrate having a front side whose surface area is 18 cm² or more, and therein is GaN crystal substrate in which, within a region of the front side of the substrate excepting the margin to 5 mm inward from the peripheral edge, the difference between the maximum and minimum Raman shifts corresponding to the E_{2H} phonon mode is 0.5 cm⁻¹ or less.

A further aspect of the present invention is a GaN crystal substrate having a front side whose surface area is 40 cm² or more, and therein is GaN crystal substrate in which, within a region of the front side of the substrate excepting the margin to 5 mm inward from the peripheral edge, the difference between the maximum and minimum Raman shifts corresponding to the E_{2H} phonon mode is 0.5 cm⁻¹ or less.

Yet another aspect of the present invention is a GaN crystal substrate having a front side whose surface area is 70 cm² or more, and therein is GaN crystal substrate in which, within a region of the front side of the substrate excepting the margin to 5 mm inward from the peripheral edge, the difference between the maximum and minimum Raman shifts corresponding to the E_{2H} phonon mode is 0.5 cm⁻¹ or less.

A still further aspect of the present invention is a GaN crystal substrate having a front side whose surface area is 10 cm² or more, and therein is GaN crystal substrate in which, within a region of the front side of the substrate excepting the margin to 5 mm inward from the peripheral edge, the difference between the maximum and minimum Raman shifts corresponding to the E_{2H} phonon mode is 0.1 cm⁻¹ or less.

In a GaN crystal substrate according to the present invention, furthermore, the average value of the half widths of the Raman scattering peaks corresponding to the E_{2H} phonon mode within a region of the front side of the substrate excepting the margin to 5 mm inward from the peripheral edge preferably is 2 cm⁻¹ or less.

Still further, in a GaN crystal substrate according to the present invention, the average value of the half widths of the Raman scattering peaks corresponding to the E_{2H} phonon mode within a region of the front side of the substrate excepting the margin to 5 mm inward from the peripheral edge more preferably is 1.5 cm⁻¹ or less.

Still another aspect of the present invention is a semiconductor device that is manufactured utilizing the gallium nitride crystal substrate.

An even further aspect of the present invention is a semiconductor device manufacturing method including a step of identifying, with regard to GaN crystal substrates having a front side whose surface area is 10 cm² or more, GaN crystal substrates in which, within a region of the front side of the substrate excepting the margin to 5 mm inward from the peripheral edge, the difference between the maximum and minimum Raman shifts corresponding to the E_{2H} phonon mode is 0.5 cm⁻¹ or less.

A still further aspect of the present invention is a method of identifying, with regard to GaN crystal substrates having a front side whose surface area is 10 cm² or more, GaN crystal substrates in which, within a region of the front side of the substrate excepting the margin to 5 mm inward from the peripheral edge, the difference between the maximum and minimum Raman shifts corresponding to the E_{2H} phonon mode is 0.5 cm⁻¹ or less.

The present invention affords GaN crystal substrates that can reduce the occurring of cracks and fractures in the GaN crystal substrate when the semiconductor devices are manufactured, semiconductor devices including them, methods of manufacturing the semiconductor devices, and methods of identifying the GaN crystal substrates.

From the following detailed description in conjunction with the accompanying drawings, the foregoing and other objects, features, aspects and advantages of the present invention will become readily apparent to those skilled in the art.

### BRIEF DESCRIPTION OF THE SEVERAL VIEWS OF THE DRAWINGS

FIG. 1 is a schematic plan view of one preferable example of the front side of a GaN crystal substrate according to the present invention;

FIG. 2A is a view illustrating the wurtzite crystalline structure of the GaN crystal, and FIG. 2B is a view illustrating the E_{2H} phonon mode;

FIG. 3 is a view illustrating an outline of the growing furnace utilized to grow the GaN crystal in embodiments of the present invention;

FIG. 4 is a schematic oblique diagram for illustratively explaining a method of measuring the wavenumber when the peaks in the Raman scattering corresponding to the E_{2H} phonon mode are at maximum, and the half-width of those maximums, in embodiments of the present invention; and

FIG. 5 is a view representing the relationship, in embodiments of the present invention, between the average value of the half widths of the Raman scattering peaks corresponding to the E_{2H} phonon mode within a region of the front side of a GaN substrate excepting the margin to 5 mm inward from the peripheral edge, and the average value of the breakdown voltages of Schottky diodes manufactured from the GaN crystal substrates.

### DETAILED DESCRIPTION OF THE INVENTION

Below, a description will be made of embodiments according to the present invention. Note that the same reference marks indicate the same portions or the corresponding portions in figures of the present invention.

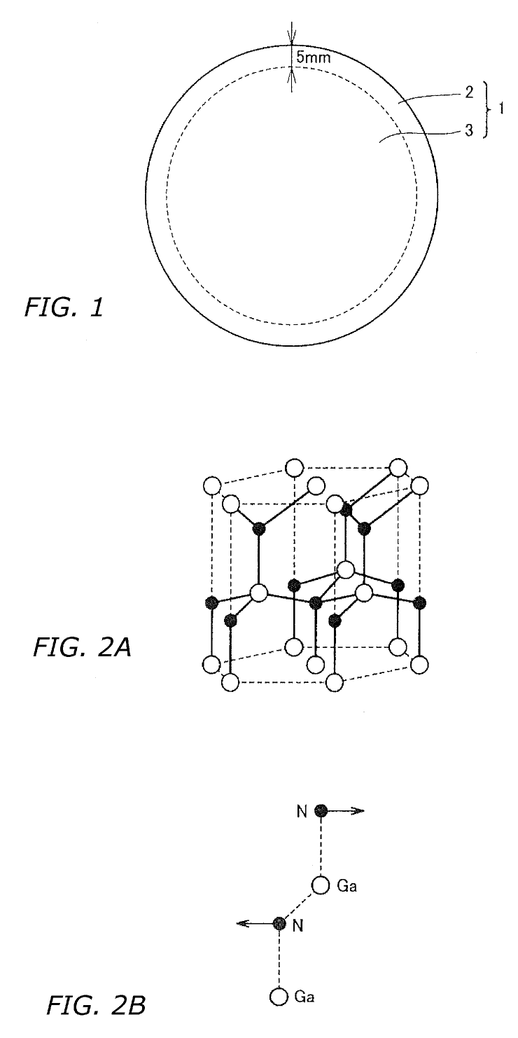

FIG. 1 is a schematic plain view of one preferable example of a surface of a GaN crystal substrate according to the present invention. Here, the GaN crystal substrate according to the present invention is characterized in that the surface area of the front side 1 is 10 cm² or more, and the difference between the maximum and minimum Raman shifts corresponding to the E_{2H} phonon mode in a region 3 (the region encircled by the dashed line in FIG. 1), the region 3 being an area excluding the margin 2 (the region between the solid line and the dashed line in FIG. 1), i.e., the margin from the circumferential edge of the front side 1 to a line 5 mm radially inward from the outer periphery, is 0.5 cm⁻¹ or less.

The above-described characteristics are attributable to the following facts. The present inventors found, as a result of concerted investigation, that as shown in FIG. 1, if semiconductor devices are manufactured utilizing the GaN crystal substrates in which the surface area of the front side 1 is 10 cm² or more, and the difference between the maximum and minimum Raman shifts corresponding to the E_{2H} phonon mode in the region 3 (the region encircled by the dashed line in FIG. 1), the region 3 being an area excluding the margin 2 (the region between the solid line and the dashed line in FIG. 1), i.e., the margin from the circumferential edge of the front side 1 to a line 5 mm radially inward from the outer periphery, is 0.5 cm⁻¹ or less, it is possible to reduce the occurring of cracks and fractures in the GaN crystal substrates when the semiconductor devices are manufactured, due to less residual strain (stress) in the GaN crystal substrates, thereby achieving the present invention.

It should be understood that the dashed line shown in FIG. 1 is an imaginary line for convenience of explanation, meaning that the line is not necessarily formed on the front side of a GaN crystal substrate according to the present invention.

The E_{2H} phonon mode will be described by citing wurtzite structure GaN crystals. The E_{2H} phonon mode is, in GaN crystal having the crystal structure composed of Ga atoms (white circles) and N atoms (black circles) shown in FIG. 2A, a mode in which N atoms are shifted within c-plane as shown in FIG. 2B.

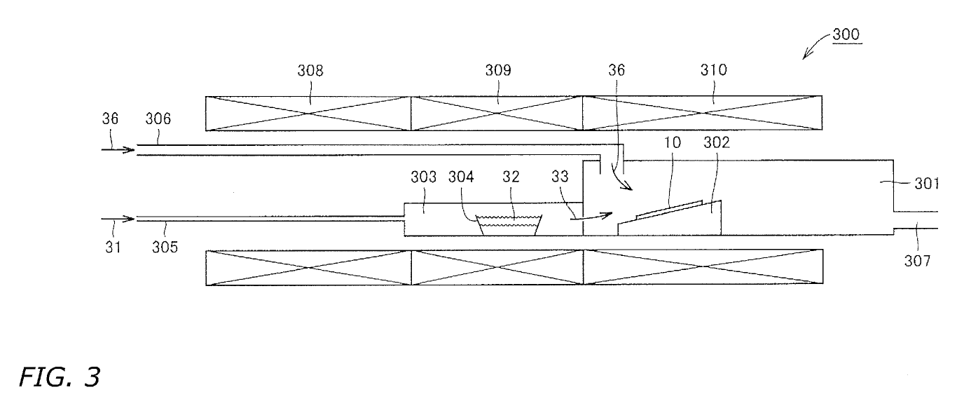

Raman shifts corresponding to the E_{2H} phonon mode within the region 3 shown in FIG. 1 is identified by wavenumber at the maximum peak of peaks corresponding to the E_{2H} phonon mode in the spectrum of Raman shifts obtained by Raman spectroscopic analysis on the region 3. It is to be noted that in Table II on page 985 of “Characterization of GaN and Related Nitrides by Raman Scattering,” by Hiroshi Harima in Materials, Vol. 51, No. 9, September 2002, pp. 983-988, The Society of Materials Science, Japan, the phonon frequency in E_{2H} phonon mode wurtzite structure GaN crystal at a temperature of 300 K is 567.6 cm⁻¹, and that in the Raman spectrum diagram of FIG. 3 of the Harima paper the wavenumber at the maximum peak among peaks corresponding to the E_{2H} phonon mode appears around 567.6 cm⁻¹.

As the surface of GaN crystal substrate is larger, it is more likely that cracks and fractures occur in the GaN crystal substrates when the semiconductor devices are manufactured. Therefore, the present invention is effective when an area of the surface of GaN crystal substrate is preferably 18 cm² or more, more preferably 40 cm² or more, and further preferably 70 cm² or more.

The difference between the maximum and minimum Raman shifts corresponding to the E_{2H} phonon mode in a region except for a region from the outer periphery in the surface to a line 5 mm radially inward from the outer periphery in the surface having an area of 10 cm² or more is preferably 0.1 cm⁻¹ or less. In this case, it is especially evident that the occurring of cracks and fractures in the GaN crystal substrates can be effectively reduced when the semiconductor devices are manufactured.

The average value of the half widths at the peaks of Raman shifts corresponding to the E_{2H} phonon mode in a region except for a region from the outer periphery in the surface of the GaN crystal substrate to a line 5 mm radially inward from the outer periphery according to the present invention is preferably 2 cm⁻¹ or less. In this case, not only the occurring of cracks and fractures in the GaN crystal substrates tends to be decreased when the semiconductor devices are manufactured, but the characteristics of the semiconductor devices manufactured by utilizing the GaN crystal substrate according to the present invention tends to be better because crystallizability is better. The above-described half width at the Raman scattering peaks corresponding to the E_{2H} phonon mode can be calculated by measuring the half-width of the peak corresponding to the E_{2H} phonon mode of spectrum of Raman shifts obtained by Raman spectroscopic analysis on a region except for a region from the outer periphery in the surface to a line 5 mm radially inward from the outer periphery (the width of wavenumber of the peak whose intensity is a half of the peak corresponding to the E_{2H} phonon mode).

The average value of the half widths at the peaks of Raman shifts corresponding to the E_{2H} phonon mode within a region except for a region from the outer periphery in surface of the GaN crystal substrate according to the present invention to a line 5 mm radially inward from the outer periphery is more preferably 1.5 cm⁻¹ or less. In this case, not only the occurring of cracks and fractures in the GaN crystal substrates tends to be decreased when the semiconductor devices are manufactured, but the characteristics of the semiconductor devices manufactured by utilizing the GaN crystal substrates according to the present invention tends to be better because crystallizability is better.

Furthermore, according to the present invention, in GaN crystal substrates having a surface area of 10 cm² or more, preferably 18 cm² or more, more preferably 40 cm² or more, and further preferably 70 cm² or more, it is possible to identify the GaN crystal substrates according to the present invention, in which the difference between the maximum and minimum Raman shifts corresponding to the E_{2H} phonon mode in a region except for a region from the outer periphery in the surface of the GaN crystal substrate to a line 5 mm radially inward from the outer periphery is 0.5 cm⁻¹ or less, preferably 0.1 cm⁻¹ or less, and to use the identified GaN crystal substrates according to the present invention to manufacture the semiconductor devices.

When the semiconductor devices are manufactured accordingly, since the occurring of cracks and fractures in the GaN crystal substrates can be reduced when the semiconductor devices are manufactured, it is possible to use GaN crystal substrates having a surface of a large area, so that the cost of manufacturing semiconductor devices tends to be reduced. The semiconductor devices can be manufactured by laminating nitride semiconductor layers by conventionally known methods onto the above-identified GaN crystal substrate according to the present invention. Also, it is understood that in the above-described manufacture of the semiconductor device, the average value of the half widths at the peaks of Raman shifts corresponding to the E_{2H} phonon mode in a region except for a region from the outer periphery in the surface of the GaN crystal substrate according to the present invention to a line 5 mm radially inward from the outer periphery is preferably 2 cm⁻¹ or less, and more preferably 1.5 cm⁻¹ or less.

The semiconductor devices include, for example, light-emitting devices such as light-emitting diodes and laser diodes; electronic devices such as rectifiers, bipolar transistors, field-effect transistors and high electron mobility transistors (HEMT); semiconductor sensors such as temperature sensors, pressure sensors, radiation sensors and visible-ultraviolet light sensors; and semiconductor devices such as surface acoustic wave (SAW) devices, vibrators, resonators, oscillators, micro electro mechanical system (MEMS) devices, and piezoelectric actuators.

### EXAMPLES

### Experiment 1

By using a growing furnace 300 whose layout is shown in FIG. 3, GaN crystal was grown by hydride vapor phase epitaxy (HVPE) method.

The growing furnace 300 included a reaction chamber 301, a substrate holder 302 for holding a seed crystal substrate 10 in the reaction chamber 301, a synthesizing chamber 303 for synthesizing Ga source gas (GaCl) 33, a gas inlet pipe 305 for introducing HCl gas 31 into the synthesizing chamber 303, a gas inlet pipe 306 for introducing N source gas (NH₃) 36 into the reaction chamber 301, an exhaust pipe 307 for exhausting the gas after reaction from the reaction chamber 301. In addition, in the synthesizing chamber 303 installed is a Ga boat 304 accommodating Ga 32, and around the reaction chamber 301, the synthesizing chamber 303, the gas inlet pipe 305 and the gas inlet pipe 306 are provided a heater 308, a heater 309, and a heater 310.

First, the seed crystal substrate 10 was placed on the substrate holder 302 in the reaction chamber 301. The seed crystal substrate 10 was GaN crystal and had a diameter of 2 inch and a thickness of 350 μm. The surface of the seed crystal substrate 10 was one that was inclined at 5 degree to Ga plane having (0001) orientation in <1100> direction and mirror-polished, and the dislocation density of the surface of the seed crystal substrate 10 was around between 5×10⁶ cm⁻² and 5×10⁷ cm⁻². Furthermore, the seed crystal substrate 10 was inclined at 10 degree to improve the uniformity of amount supplied of the source gas in the surface of the seed crystal substrate 10.

Next, while the seed crystal substrate 10 was heated to keep the surface temperature of the seed crystal substrate 10 at 1250 degree Celsius and the seed crystal substrate 10 was rotated at a speed of 60 rpm, source gases including the Ga source gas 33 and the N source gas 36 were introduced into the reaction chamber 301. Accordingly, the GaN crystal was grown on the surface of the seed crystal substrate 10. The Ga source gas 33 had a partial pressure of 0.05 atm, and the N source gas 36 had a partial pressure of 0.1 atm, and H₂ gas was used as a carrier gas.

The Ga source gas 33 was generated by heating the Ga boat 304 installed in the synthesizing chamber 303 up to 800 degree Celsius, and introducing the HCl gas 31 through the gas inlet pipe 305 into the synthesizing chamber 303 to react the Ga 32 in the Ga boat 304 with the HCl gas 31. The HCl gas 31 was introduced into the synthesizing chamber 303 with the H₂ gas as a carrier gas.

Then, GaN crystal had been grown on the surface of the seed crystal substrate 10 for 100 hours. The surface of the grown GaN crystal was inclined at 5 degree to the surface of the seed crystal substrate 10, and was flat and not-inclined (0001) plane. The thickness of the grown GaN crystal varied across the surface of the GaN crystal in conjunction with the formation of the (0001) plane: the thickest portion is about 10 mm; and the thinnest portion is about 6 mm.

The GaN crystal substrate having a thickness of 350 μm was cut out from a portion near the surface of the GaN crystal grown as described, tilting it against (0001) plane of the surface of the GaN crystal at 5 degree in <1100> direction. Then, after the above-mentioned (0001) plane, which was the surface of GaN crystal substrate (Ga plane), was mirror-polished, the dislocation density of the surface was measured. The high-quality GaN crystal substrate having an extremely low dislocation density, more specifically, between 2×10⁴ cm⁻² and 1×10⁵ cm⁻², was obtained.

Sixty GaN crystal substrates having a diameter of 2 inch were manufactured as described above, and Raman shifts corresponding to the E_{2H} phonon mode in a region except for a region from the outer periphery in the surface of GaN crystal substrate to a line 5 mm radially inward from the outer periphery and the half width at the peak of the Raman shifts were measured at 500 points with 2 mm pitch in length and width directions on each of the substrates. The measured 60 GaN crystal substrates were classified into six stages according to the difference between the maximum and minimum Raman shifts corresponding to the E_{2H} phonon mode, and the number of GaN crystal substrates in which cracks or fractures occurred when the semiconductor devices were manufactured by utilizing these GaN crystal substrates was investigated. The results are shown in Table 1. It is noted that the Raman scattering peaks corresponding to the E_{2H} phonon mode varied in response to measurement conditions, but was in the range between 566.0 cm⁻¹ and 568.6 cm⁻¹.

TABLE I

| | No cracking or | Cracking | Fracturing |
|---|---|---|---|
| Raman shifts corresponding to | fracturing | occurred | occurred |
| E₂ phonon mode (cm⁻¹ ) | (# of substrates) | (# of substrates) | (# of substrates) |
| 0.1 or less | 10 | 0 | 0 |
| Greater than 0.1 but 0.3 or less | 9 | 1 | 0 |
| Greater than 0.3 but 0.5 or less | 9 | 1 | 0 |
| Greater than 0.5 but 0.7 or less | 7 | 2 | 1 |
| Greater than 0.7 but 0.9 or less | 4 | 3 | 3 |
| 0.9 or more | 0 | 5 | 5 |

As shown in Table I, it becomes apparent that if the difference between the maximum and minimum Raman shifts corresponding to the E_{2H} phonon mode is 0.5 cm⁻¹ or less, it is possible to reduce the occurring of cracks and fractures when the semiconductor devices are manufactured. Especially, if it is 0.1 cm⁻¹ or less, it is possible to significantly reduce the cracks and fractures when the semiconductor devices are manufactured.

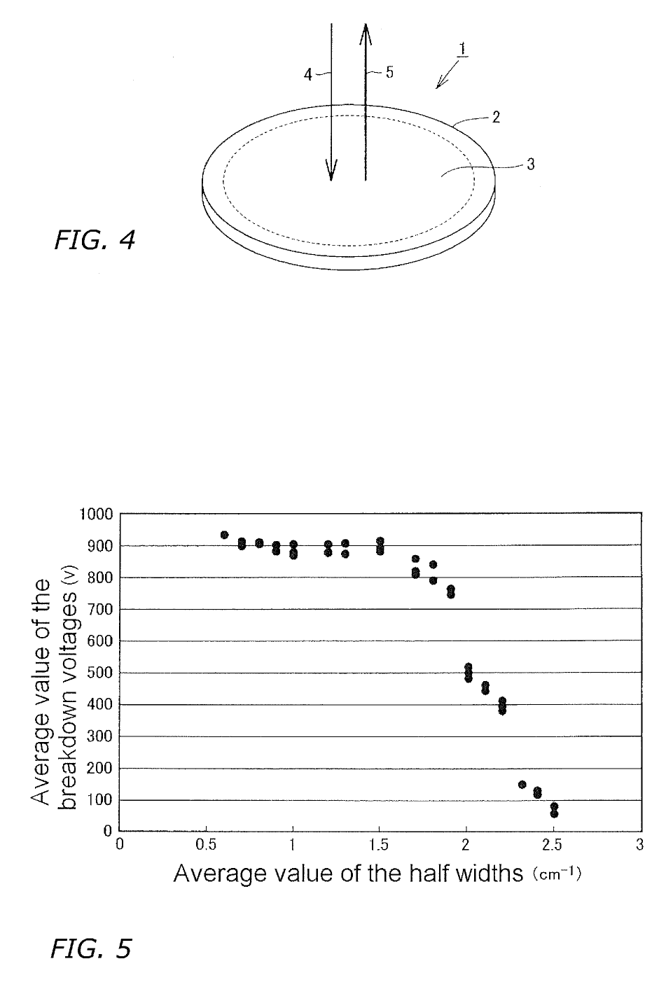

Raman shifts corresponding to the E_{2H} phonon mode was measured as follows. First, as a light source, an Ar laser was used to emit Ar laser light having a wavelength of 514.5 nm through a spectrometer slit (100 μm). The spot radius of laser light was about 2 μm because a 50× object lens was used, and exposure was once every 30 seconds in total. Regarding the intensity of laser light, the oscillation output was 0.1 W (about 10 mW at the surface of GaN crystal substrate). Then, as shown in a schematic perspective view of FIG. 4, the Ar laser light 4 was applied to the region 3 (except for the region 2 from circumferential edge of the front side 1 of GaN crystal substrate to a line 5 mm radially inward from the outer periphery) perpendicularly to the front side 1, and then the reflected light 5 was detected at a back scattering location in the c-axis direction while the temperature of the surface of the GaN crystal substrate was 20 degree Celsius. In order to calibrate the wavenumber, a method of approximating four emission line spectrum of the Ne lamp by quadratic functions was employed. The measured numeric data was approximated by Lorentz functions. At the obtained spectrum of Raman shifts, the wavenumber at the maximum peak and the half-width of the peak corresponding to the E_{2H} phonon mode were obtained.

### Experiment 2

Thirty GaN crystal substrates were manufactured in the same way and with the same conditions as those in Embodiment 1 except that the diameter was 3 inch. Raman shifts corresponding to the E_{2H} phonon mode was measured evenly at 300 points in the surface of the GaN crystal substrate having a diameter of 3 inch, more specifically, in a region except for a region from the outer periphery to a line 5 mm radially inward from the outer periphery. It is noted that Raman shifts corresponding to the E_{2H} phonon mode was measured in the same way and with the same conditions as those of Embodiment 1.

Thirty GaN crystal substrates measured as described were classified into 6 stages according to the difference between the maximum and minimum Raman shifts corresponding to the E_{2H} phonon mode, and the number of the GaN crystal substrates in which cracks or fractures occurred when the semiconductor devices were manufactured by utilizing the GaN crystal substrates was investigated. The results are shown in Table II.

TABLE II

| | No cracking or | Cracking | Fracturing |
|---|---|---|---|
| Raman shifts corresponding to | fracturing | occurred | occurred |
| E₂ phonon mode (cm⁻¹ ) | (# of substrates) | (# of substrates) | (# of substrates) |
| 0.1 or less | 4 | 0 | 0 |
| Greater than 0.1 but 0.3 or less | 4 | 1 | 0 |
| Greater than 0.3 but 0.5 or less | 3 | 1 | 0 |
| Greater than 0.5 but 0.7 or less | 3 | 2 | 1 |
| Greater than 0.7 but 0.9 or less | 2 | 2 | 2 |
| 0.9 or more | 0 | 2 | 3 |

As shown in Table II, the following fact becomes apparent. If the difference between the maximum and minimum Raman shifts corresponding to the E_{2H} phonon mode is 0.5 cm⁻¹ or less, it is possible to reduce the occurring of cracks and fractures when the semiconductor devices are manufactured. If it is 0.1 cm⁻¹ or less, it is possible to significantly reduce the occurring of cracks and fractures when the semiconductor devices are manufactured.

### Experiment 3

Twenty GaN crystal substrates were manufactured in the same way and with the same conditions as those in Embodiment 1 except that the diameter was 4 inch. Raman shifts corresponding to the E_{2H} phonon mode was measured evenly at 300 points in the surface of the GaN crystal substrate having a diameter of 4 inch, more specifically, in a region except for a region from the outer periphery to a line 5 mm radially inward from the outer periphery. It is noted that Raman shifts corresponding to the E_{2H} phonon mode was measured in the same way and with the same conditions as those of Embodiment 1.

Twenty GaN crystal substrates measured as described were classified into 6 stages according to the difference between the maximum and minimum Raman shifts corresponding to the E_{2H} phonon mode, and the number of the GaN crystal substrates in which cracks or fractures occurred when the semiconductor devices were manufactured by utilizing the GaN crystal substrates was investigated. The results are shown in Table III.

TABLE III

| | No cracking or | Cracking | Fracturing |
|---|---|---|---|
| Raman shifts corresponding to | fracturing | occurred | occurred |
| E₂ phonon mode (cm⁻¹ ) | (# of substrates) | (# of substrates) | (# of substrates) |
| 0.1 or less | 3 | 0 | 0 |
| Greater than 0.1 but 0.3 or less | 3 | 0 | 0 |
| Greater than 0.3 but 0.5 or less | 3 | 1 | 0 |
| Greater than 0.5 but 0.7 or less | 2 | 1 | 0 |
| Greater than 0.7 but 0.9 or less | 1 | 2 | 1 |
| 0.9 or more | 0 | 1 | 2 |

As shown in Table III, the following fact becomes apparent. If the difference between the maximum and minimum Raman shifts corresponding to the E_{2H} phonon mode is 0.5 cm⁻¹ or less, it is possible to reduce the occurring of cracks and fractures when the semiconductor devices are manufactured. If it is 0.1 cm⁻¹ or less, it is possible to significantly reduce the occurring of cracks and fractures when the semiconductor devices are manufactured.

### Embodiment 4

An n-type GaN thin film having a thickness of 15 μm and a carrier concentration of 1×10¹⁷ cm⁻³ was deposited by MOCVD method onto surfaces of each of thirty nine GaN crystal substrates in which cracks or fractures did not occur when the semiconductor devices were manufactured in Embodiment 1. Then, Schottky electrodes composed of Au and having a diameter of 200 μm were formed onto the surfaces of the n-type GaN thin films at 2 mm pitch, ohmic electrodes composed of Ti/Al were formed over the rear surfaces of the GaN crystal substrates, and finally one hundred Schottky diodes as the semiconductor devices were manufactured from the GaN crystal substrates.

Next, the Schottky diodes were evaluated by applying a reverse voltage across the Schottky electrode and the ohmic electrode of each of the Schottky diodes manufactured as described and by measuring the breakdown voltages. FIG. 5 shows the relationship between the average value of the half widths at the peaks of Raman shifts corresponding to the E_{2H} phonon mode in a region except for a region from the outer periphery in the surface of the thirty nine GaN crystal substrates to a line 5 mm radially inward from the outer periphery, and the average value of the breakdown voltages of Schottky diodes manufactured from the GaN crystal substrates. It should be noted that in FIG. 5, the vertical axis indicates the average value of breakdown voltages of Schottky diodes; the horizontal axis indicates the average value of the half widths. Accordingly, the higher the average value of the breakdown voltages along the vertical axis was, the better the characteristics of the Schottky diodes were.

As shown in FIG. 5, if the average value of the half widths at the peaks of Raman shifts corresponding to the E_{2H} phonon mode in a region except for a region from the outer periphery in the surface of the GaN crystal substrate to a line 5 mm radially inward from the outer periphery was 2 cm⁻¹ or less, the average value of the breakdown voltages of the Schottky diodes became higher. If the average value of the half widths is 1.5 cm⁻¹ or less, the average value of the breakdown voltages became extremely high.

Only selected embodiments have been chosen to illustrate the present invention. To those skilled in the art, however, it will be apparent from the foregoing disclosure that various changes and modifications can be made herein without departing from the scope of the invention as defined in the appended claims. Furthermore, the foregoing description of the embodiments according to the present invention is provided for illustration only, and not for limiting the invention as defined by the appended claims and their equivalents.

What is claimed is:

1. A gallium nitride crystal substrate having a front side whose surface area is 10 cm² or more, the gallium nitride crystal substrate characterized in that within a region of the front side of the gallium nitride crystal substrate excepting the margin to 5 mm inward from the peripheral edge, the difference between the maximum and minimum Raman shifts corresponding to the E_{2H} phonon mode is 0.5 cm⁻¹ or less.

2. A gallium nitride crystal substrate having a front side whose surface area is 18 cm² or more, the gallium nitride crystal substrate characterized in that within a region of the front side of the gallium nitride crystal substrate excepting the margin to 5 mm inward from the peripheral edge, the difference between the maximum and minimum Raman shifts corresponding to the E_{2H} phonon mode is 0.5 cm⁻¹ or less.

3. A gallium nitride crystal substrate having a front side whose surface area is 40 cm² or more, the gallium nitride crystal substrate characterized in that within a region of the front side of the gallium nitride crystal substrate excepting the margin to 5 mm inward from the peripheral edge, the difference between the maximum and minimum Raman shifts corresponding to the E_{2H} phonon mode is 0.5 cm⁻¹ or less.

4. A gallium nitride crystal substrate having a front side whose surface area is 70 cm² or more, the gallium nitride crystal substrate characterized in that within a region of the front side of the gallium nitride crystal substrate excepting the margin to 5 mm inward from the peripheral edge, the difference between the maximum and minimum Raman shifts corresponding to the E_{2H} phonon mode is 0.5 cm⁻¹ or less.

5. A gallium nitride crystal substrate having a front side whose surface area is 10 cm² or more, the gallium nitride crystal substrate characterized in that within a region of the front side of the gallium nitride crystal substrate excepting the margin to 5 mm inward from the peripheral edge, the difference between the maximum and minimum Raman shifts corresponding to the E_{2H} phonon mode is 0.1 cm⁻¹ or less.

6. The gallium nitride crystal substrate set forth in any of claims 1 through 5, characterized in that the average value of the half widths of the Raman scattering peaks corresponding to the E_{2H} phonon mode within a region of the front side of the substrate excepting the margin to 5 mm inward from the peripheral edge preferably is 2 cm⁻¹ or less.

7. The gallium nitride crystal substrate set forth in any of claims 1 through 5, characterized in that the average value of the half widths of the Raman scattering peaks corresponding to the E_{2H} phonon mode within a region of the front side of the substrate excepting the margin to 5 mm inward from the peripheral edge preferably is 1.5 cm⁻¹ or less.

8. A semiconductor device manufactured utilizing the gallium nitride crystal substrate set forth in any of claims 1 through 5.

9. A semiconductor device manufacturing method including a step of identifying, with regard to GaN crystal substrates having a front side whose surface area is 10 cm² or more, GaN crystal substrates in which, within a region of the front side of the substrate excepting the margin to 5 mm inward from the peripheral edge, the difference between the maximum and minimum Raman shifts corresponding to the E_{2H} phonon mode is 0.5 cm⁻¹ or less.

10. A method of identifying, with regard to GaN crystal substrates having a front side whose surface area is 10 cm² or more, GaN crystal substrates in which, within a region of the front side of the substrate excepting the margin to 5 mm inward from the peripheral edge, the difference between the maximum and minimum Raman shifts corresponding to the E_{2H} phonon mode is 0.5 cm⁻¹ or less.
